(19) United States
(12) Patent Application Publication
(10) Pub. No.: US 2023/0402384 A1
(43) Pub. Date: Dec. 14, 2023

(54) GRAPHENE-METAL HYBRID INTERCONNECT

(71) Applicant: Taiwan Semiconductor Manufacturing Co., Ltd., Hsinchu (TW)

(72) Inventors: Jian-Hong LIN, Yulin (TW); Yinlung LU, Hsinchu (TW); Jun HE, Zhubei City (TW); Hsuan-Ming HUANG, Hsinchu (TW); Hsin-Chun CHANG, Taipei (TW)

(73) Assignee: Taiwan Semiconductor Manufacturing Co., Ltd., Hsinchu (TW)

(21) Appl. No.: 17/835,924

(22) Filed: Jun. 8, 2022

(51) Int. Cl. H01L 23/532; H01L 21/768

(52) U.S. Cl. CPC H01L 23/53276; H01L 23/53233; H01L 23/53238; H01L 21/76877; H01L 21/76886; H01L 21/76849; H01L 23/5226

(57) ABSTRACT

Material properties of graphene can be leveraged to improve performance of interconnects in an integrated circuit. One way to circumvent challenges involved in depositing graphene onto a copper surface is to incorporate graphene into the bulk metal layer to create a hybrid metal/graphene interconnect structure. Such a hybrid structure can be created instead of, or in addition to, forming a graphene film on the metal surface as a metal capping layer. A first method for embedding graphene into a copper damascene layer is to alternate the metal fill process with graphene deposition to create a composite graphene matrix. A second method is to implant carbon atoms into a surface layer of metal. A third method is to disperse graphene flakes in a damascene copper plating solution to create a distributed graphene matrix. Any combination of these methods can be used to enhance conductivity of the interconnect.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (FinFETs). Such scaling down has increased the complexity of semiconductor manufacturing processes and the impact on device performance and reliability.

### BRIEF DESCRIPTION OF THE DRAWINGS

Aspects of the present disclosure are best understood from the following detailed description when read with the accompanying figures. It is noted that, in accordance with common practice in the industry, various features are not drawn to scale. In fact, the dimensions of the various features may be arbitrarily increased or reduced for clarity of discussion.

FIG. 1 is a cross-sectional view of a pair of transistors coupled to an interconnect structure embedded with graphene elements, in accordance with some embodiments.

FIG. 2 is a flow diagram of a method for fabricating the structure shown in FIG. 1, in accordance with some embodiments.

FIG. 3 is a magnified cross-sectional view of a damascene interconnect structure incorporating multi-layer graphene films, in accordance with some embodiments.

FIG. 4 is a flow diagram of a method for fabricating the damascene interconnect structure shown in FIG. 3, in accordance with some embodiments.

FIGS. 5A-5E are cross-sectional views of the interconnect structure shown in FIG. 3 at various stages of its fabrication process, in accordance with some embodiments.

FIG. 6 is a magnified cross-sectional view of a damascene interconnect structure incorporating implanted carbon atoms and a graphene capping layer, in accordance with some embodiments.

FIG. 7 is a flow diagram of a method for implanting damascene metal layers with carbon atoms, as shown in FIG. 6, in accordance with some embodiments.

FIGS. 8A-8D are cross-sectional views of the interconnect structure shown in FIG. 6 at various stages of its fabrication process, in accordance with some embodiments.

FIG. 9 is a magnified cross-sectional view of a damascene interconnect structure incorporating graphene flakes or carbon nanotubes, in accordance with some embodiments.

FIG. 10 is a flow diagram of a method for fabricating damascene metal layers incorporating graphene flakes, as shown in FIG. 9, in accordance with some embodiments.

FIGS. 11A-11E are cross-sectional views of the interconnect structure shown in FIG. 9 at various stages of its fabrication process, in accordance with some embodiments.

FIGS. 12A-12C are cross-sectional views of damascene interconnect structures incorporating multiple forms of graphene, in accordance with some embodiments.

### DETAILED DESCRIPTION

The following disclosure provides different embodiments, or examples, for implementing different features of the provided subject matter. Specific examples of components and arrangements are described below to simplify the present disclosure. These are, of course, merely examples and are not intended to be limiting. For example, the formation of a first feature on a second feature in the description that follows may include embodiments in which the first and second features are formed in direct contact, and may also include embodiments in which additional features may be formed that are between the first and second features, such that the first and second features are not in direct contact.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “nominal” as used herein refers to a desired, or target, value of a characteristic or parameter for a component or a process operation, set during the design phase of a product or a process, together with a range of values above and/or below the desired value. The range of values can be due to slight variations in manufacturing processes or tolerances.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

The term “vertical,” as used herein, means nominally perpendicular to the surface of a substrate.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

Graphene is a molecular form of carbon graphite, in which carbon atoms are arranged in a planar, or two-dimensional, hexagonal lattice. Graphene has unique material properties, including superior electrical and thermal conductivity, as well as favorable mechanical properties. The structure of graphene provides a long mean free path for movement of electric charge and allows for conduction of high current densities. Consequently, graphene has one of the highest electron mobility of all materials used in the electronics industry—significantly higher (e.g., about 100 times higher) than the electron mobility of silicon—and the electrical resistivity of graphene is significantly lower (e.g., about one-third lower) than that of copper. Graphene films that are one atomic layer thick can have very high tensile strength while remaining transparent.

Based on its properties, graphene can be used in interconnect designs. In addition to reducing resistivity and increasing thermal conductivity of interconnects, graphene may be used as a diffusion barrier to limit electromigration, which has been a longstanding failure mechanism in interconnect designs. Diffusion barriers may be desirable for copper interconnects for additional reasons. For example, a diffusion barrier can be used to prevent copper from reacting with neighboring insulators, such as silicon oxides (e.g., Sift), which could cause the copper to oxidize, or polyimide that could cause corrosion and associated material defects.

Copper interconnects have been widely used in the production of advanced integrated circuits. Copper interconnects can be formed using a damascene, or inlay, process. First, a pattern of trenches is formed in an insulating material, and then the trenches are filled with copper using a plating process (e.g., electroplating or electro-less plating) in a liquid plating solution. The damascene process does not require patterning and etching copper. In a dual damascene process, trenches for vias (vertical connections) and metal lines (horizontal connections) can be formed and filled together as a single structure. Depositing graphene films with sufficient adhesion to copper interconnects can be challenging. High temperatures in a range from about 500° C. to about 1000° C. may be required when using a chemical vapor deposition (CVD) process. Growing sufficiently thick graphene layers on copper to achieve desired conductivity improvements can also be challenging because the growth rate of graphene is highly dependent on the carbon solubility of the substrate metal.

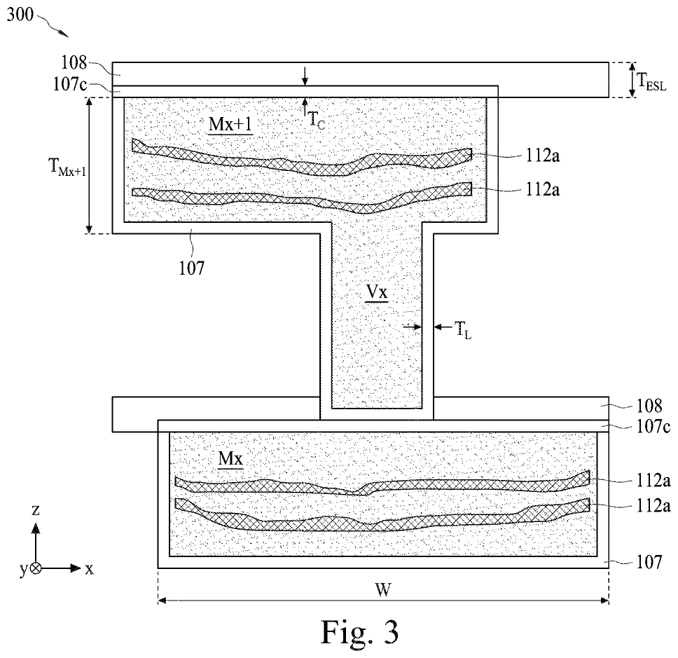

One way to circumvent such challenges involved in depositing graphene onto a copper surface is to incorporate graphene directly into the bulk metal layer to create a hybrid metal/graphene interconnect structure. Such a hybrid structure can be created instead of, or in addition to, selectively forming a graphene film on the metal surface as a metal capping layer. A first method is to alternate the metal fill process with graphene deposition to create a composite graphene matrix. A second method is to implant carbon atoms into a surface layer of metal. A third method for embedding graphene into a copper damascene layer is to disperse graphene flakes in a damascene copper plating solution to create a distributed graphene matrix. These methods are described in detail below, with respect to exemplary structures shown in FIGS. 3, 6, and 9, respectively.

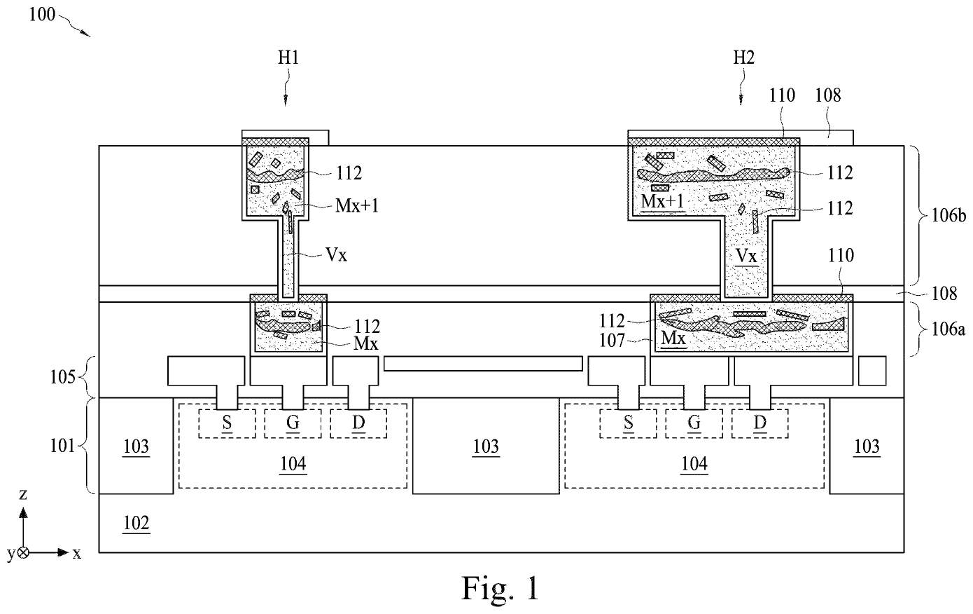

FIG. 1 shows a cross-sectional view of an integrated circuit 100 incorporating hybrid graphene/metal interconnect structures, e.g., H1 and H2, according to some embodiments. Integrated circuit 100 includes a transistor structure 101, a substrate 102, a contact layer 105, and inter-layer dielectric (ILD) layers 106a and 106b. Hybrid graphene/metal interconnect structures H1 and H2 are fabricated above transistor layer 101 and provide connections between contacts to terminals of transistors 104, and among various transistors 104 throughout integrated circuit 100. For example, H1 may be coupled to the gate terminal of a transistor, while H2 connects gate and drain terminals of another transistor, as shown in FIG. 1. Hybrid graphene/metal interconnect structures H1 and H2 each include a lower metal line “Mₓ,” an upper metal line “Mₓ₊₁,” and a vertical connection (e.g., in the z-direction), or via “Vₓ,” between the upper and lower metal lines—when Mₓ represents, for example, metal 1, and Mₓ₊₁ represents metal 2; when Mₓ represents metal 2 and Mₓ₊₁ represents metal 3; and so on. Liners 107 may be formed on interior surfaces of one or both metal lines as well as via Vₓ. ILD 106a and 106b provide electrical insulation around the metal lines and vias. Etch stop layers 108 can be used to delineate adjacent ILD 106a and 106b and to protect underlying films from damage from deposition of low-k dielectrics, such as SiN, silicon carbon nitride (SiCN), silicon carbide (SiC), aluminum oxide (Al₂O₃), and aluminum nitride (AlN). In some embodiments, etch stop layers form compressive stress and improve adhesion of adjacent layers. Each hybrid graphene/metal interconnect structure H1, H2 may also include optional graphene capping layers 110 on upper metal lines, in addition to elements of embedded graphene 112 in both upper and lower metal lines. In some embodiments, embedded graphene 112 can also be incorporated into vias Vₓ.

Integrated circuit 100 may include additional vias and metal lines stacked on top of hybrid graphene/metal interconnect structures H1 and H2. Additional vias and metal lines may also be hybrid interconnect structures, or they may be copper damascene structures without the addition of graphene, or combinations thereof.

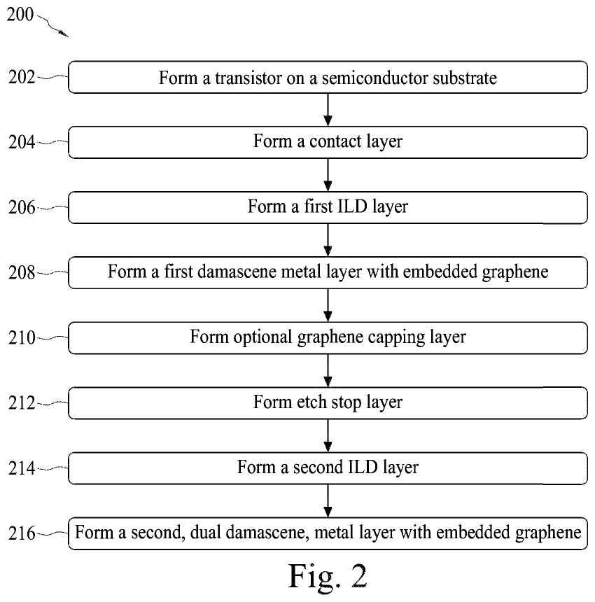

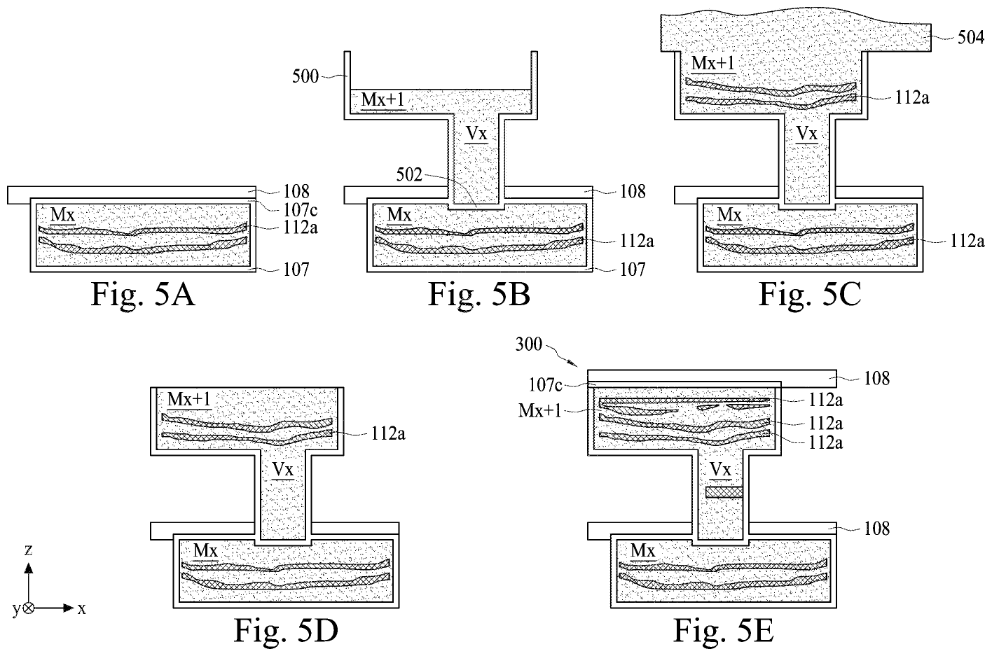

FIG. 2 illustrates a method 200 for fabricating integrated circuit 100 that includes hybrid graphene/metal interconnect structures H1 and H2, according to some embodiments. For illustrative purposes, operations illustrated in FIG. 2 will be described with reference to exemplary processes for fabricating hybrid graphene/metal interconnect structures H1 and H2 as illustrated in FIGS. 5A-5E, 8A-8D, and 11A-11E which are cross-sectional views of hybrid graphene/metal interconnect structures at various stages of their fabrication, according to some embodiments. Operations of method 200 can be performed in a different order, or not performed, depending on specific applications. It is noted that method 200 may not produce a complete integrated circuit 100. Accordingly, it is understood that additional processes can be provided before, during, or after method 200, and that some of these additional processes may be briefly described herein.

Referring to FIG. 2, in operation 202, transistors 104 are formed on substrate 102 as shown in FIG. 1, in accordance with some embodiments. As used herein, the term “substrate” describes a material onto which subsequent material layers are added. Substrate 102 itself may be patterned. Materials added on substrate 102 may be patterned or may remain unpatterned. Substrate 102 can be a bulk semiconductor wafer or the top semiconductor layer of a semiconductor-on-insulator (SOI) wafer (not shown), such as silicon-on-insulator. In some embodiments, substrate 102 can include a crystalline semiconductor layer with its top surface parallel to (100), (110), (111), or c-(0001) crystal plane. Alternatively, substrate 102 may be made from an electrically non-conductive material, such as a glass, sapphire, or plastic. Substrate 102 can be made of a semiconductor material, such as silicon (Si). In some embodiments, substrate 102 can include (i) an elementary semiconductor, such as germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Further, substrate 102 can be doped with p-type dopants (e.g., boron (B), indium (In), aluminum (Al), or gallium (Ga)) or n-type dopants (e.g., phosphorus (P) or arsenic (As)). In some embodiments, different portions of substrate 102 can have opposite type dopants.

Transistor structure 101 includes shallow trench isolation (STI) regions 103 and transistors 104, each formed with a source S, gate G, and drain D, as illustrated schematically in FIG. 1. Transistors 104 are electrically isolated from one another by STI regions 103. In some embodiments, transistors 104 can be, for example, bipolar junction transistors (BJTs), planar metal oxide semiconductor field effect transistors (MOSFETs), three-dimensional MOSFETs (e.g., FinFETs, nanowire FETs, and gate-all-around FETs (GAAFETs)), or combinations thereof.

STI regions 103 can be formed adjacent to, or between transistors 104. STI regions 103 can be deposited and then etched back to a desired height. Insulating material in STI regions 103 can include, for example, silicon oxide (SiO₂), silicon nitride (SiN), silicon oxynitride (SiON), fluoride-doped silicate glass (FSG), a low-k dielectric material, and/or other suitable insulating material. In some embodiments, the term “low-k” refers to a low dielectric constant. In the field of semiconductor device structures and manufacturing processes, low-k refers to a dielectric constant that is less than the dielectric constant of Sift. (e.g., less than 3.9). In some embodiments, STI regions 103 can include a multi-layered structure. In some embodiments, the process of depositing the insulating material can include any deposition method suitable for flowable dielectric materials (e.g., flowable silicon oxide). For example, flowable silicon oxide can be deposited for STI regions 103 using a flowable chemical vapor deposition (FCVD) process. The FCVD process can be followed by a wet anneal process. In some embodiments, the process of depositing the insulating material can include depositing a low-k dielectric material to form a liner. In some embodiments, a liner made of another suitable insulating material can be placed between STI region 103 and adjacent transistors 104. In some embodiments, STI regions 103 may be annealed and polished to be co-planar with a top surface of transistors 104.

Referring to FIG. 2, in operation 204, contact layer 105 is formed above transistor structure 101 as shown in FIG. 1, in accordance with some embodiments. Contact layer 105 provides electrical connections between transistors 104 and hybrid graphene/metal interconnect structures H1 and H2. The process of forming contact layer 105 can include forming metal silicide layers and/or conductive regions (contacts) within contact openings in an ILD material. The contacts provide electrical connections to source, gate, and drain terminals of transistors 104. In some embodiments, the metal used to form metal silicide layers of contact layer 105 can include one or more of tungsten (W), cobalt (Co), titanium (Ti), and nickel (Ni). In some embodiments, contact metal is deposited by atomic layer deposition (ALD), plasma vapor deposition (PVD), plasma enhanced vapor deposition (PECVD), or CVD, in a reactor to form diffusion barrier layers (not shown) along surfaces of contact layer 105. The deposition of diffusion barrier layers can be followed by a high temperature rapid thermal annealing (RTP) process to form metal silicide layers.

The process of forming conductive regions of contact layer 105 can include deposition of a conductive material followed by a polishing process to co-planarize top surfaces of the conductive regions with top surfaces of insulating material surrounding contact layer 105. The conductive materials can be one or more of W, Co, Ti, aluminum (Al), copper (Cu), gold (Au), silver (Ag), or another suitable conductive material, a metal alloy, or a stack of various metals or metal alloys that may include layers, such as a titanium nitride (TiN) layer. The conductive materials can be deposited by, for example, CVD, PVD, PECVD, or ALD. The polishing process for co-planarizing the conductive region with the top surface of contact layer 105 can be a chemical-mechanical planarization (CMP) process. In some embodiments, the CMP process can use a silicon or an aluminum abrasive slurry with abrasive concentrations ranging from about 0.1% to about 3%. In some embodiments, the abrasive slurry may have a pH level less than about 7 for W metal, or a pH level greater than about 7 for Co or Cu metals in the conductive regions.

Referring to FIG. 2, in operation 206, ILD 106a is formed above contact layer 105 as shown in FIG. 1, in accordance with some embodiments. ILD 106a can be about 1050 Å to about 1350 Å of an insulating material, such as silicon dioxide (Sift), fluorosilicate glass (FSG), hard breakdown (HBD), a low-k silicon oxycarbide (“low-k” SiOC/LK5/LK6), an extreme low-k dielectric material (e.g., silicon oxycarbide nitride (“ELK” SiOCN/LK9S)), and combinations thereof. ILD 106a can be made of a single insulating material or a layered stack that includes multiple insulating materials. Such materials have dielectric constants, κ, ranging from about 3.9 for Sift to about 2.5 for ELK. Low-k and extreme low-k dielectrics may vary in their respective carbon concentrations such that a higher concentration of carbon in the SiOC material causes the dielectric constant to be lower.

Referring to FIG. 2, in operation 208, lower metal line Mₓ is formed to include embedded graphene 112, as shown in FIG. 1, in accordance with some embodiments. To form lower metal line Mₓ, a trench can be etched in ILD 106a to a depth that, when filled with metal, achieves a desired metal thickness, e.g., 600 Å-1000 Å. The trench can be filled with a metal (e.g., copper) by electroplating, electro-less plating, or another suitable process, to form lower metal line Mₓ. In some embodiments, a metal line pattern density characterizing lower metal line Mₓ is in a range from about 19% to about 41%. Graphene 112 can be embedded in hybrid damascene metal lines Mₓ and Mₓ₊₁ in different forms and using different methods, as described in detail below with respect to FIGS. 3, 6, and 9.

The metal fill process may incorporate a liner 107 prior to electroplating the bulk metal. In some embodiments, the metal and/or liner 107 can be made of, for example, an aluminum-copper alloy (AlCu), W, Ti, TiN, Au, Ag, other metal alloys, a metal nitride material, or another suitable metal. Liner 107 can be a thin layer that acts as a diffusion barrier to prevent conductive metal from migrating out of metal lines Mₓ and Mₓ₊₁ into the adjacent ILD. Liner 107 can also enhance properties of the conductive metal filling of metal line Mₓ. In some embodiments, a metal line thickness, e.g., T_{Mx+1}, is measured from the bottom of liner 107 to the bottom of graphene capping layer 110, to include both the thickness of liner 107 and the bulk metal. In some embodiments, liners 107 can each have a thickness, T_{L}, based on a thickness of upper metal line Mₓ₊₁. For example, T_{L} can be in a range from about T_{Mx+1}/10 to T_{Mx+1}/4.

Referring to FIG. 2, in operation 210, an optional graphene capping layer 110 can be formed on lower metal line Mₓ, as shown in FIG. 1, in accordance with some embodiments. Graphene capping layer 110 can be formed in various ways as described below with respect to FIGS. 3, 6, and 9. In some embodiments, optional graphene capping layers 110 each have a thickness, T_{C}, based on a thickness of upper metal line Mₓ₊₁. For example, T_{C} can be less than about T_{Mx+1}/10.

Referring to FIG. 2, in operation 212, etch stop layer 108 can be formed on lower metal line Mₓ, as shown in FIG. 1, in accordance with some embodiments. In some embodiments, etch stop layer 108 includes one or more of SiCN, SiC, SiN, AlN, Al₂O₃, SiO₂, or other materials that tend to be more etch-resistant than low-k ILD materials, such as SiOC. In some embodiments, etch stop layer 108 can be a single blocking layer having a thickness in a range from about 100 Å to about 150 Å. In some embodiments, etch stop layer 108 can be a multi-layer stack that includes, for example, a blocking layer and a TEOS capping layer. In some embodiments, etch stop layer 108 has a thickness, T_{ESL}, based on a thickness of upper metal line Mₓ₊₁. For example, T_{ESL} can be in a range from about T_{Mx+1}/15 to T_{Mx+1}/4. It is noted that thicknesses T_{C}, T_{L}, T_{ESL}, and T_{Mx+1} are indicated in the magnified cross-sectional view shown in FIG. 3

Referring to FIG. 2, in operation 214, ILD 106b can be formed above lower metal line Mₓ as shown in FIG. 1, in accordance with some embodiments. ILD 106b can be formed in a similar manner as ILD layer 106a, as described above with respect to operation 206. For example, ILD 106b can be formed as another insulating low-k or ELK dielectric similar to ILD 106a, as described above. In some embodiments, ILD 106b can be about 100 Å thicker than ILD 106a and in a range from about 1150 Å to about 1450 Å.

Referring to FIG. 2, in operation 216, a via opening and a trench for upper metal line Mₓ₊₁ can be formed together as a dual damascene trench as shown in FIG. 1, in accordance with some embodiments. Etching the dual damascene trench can use a process similar to the process for forming contact openings in ILD 106a, as described above. The dual damascene trench can then be filled with copper using a dual damascene process, in accordance with some embodiments. In some embodiments, a single damascene process can be used. The metal fill plating process can be altered to embed graphene into upper metal line Mₓ₊₁, as described below with respect to FIGS. 3, 6, and 9. Operations 210-214 can then be repeated to form additional vias and metal lines above Mₓ₊₁. Embedding graphene into bulk metal within the interconnect structure serves to enhance material properties of the entire metal layer with the superior properties of graphene.

FIG. 3 shows a cross-sectional view of a multi-layer interconnect structure 300, e.g., a multi-layer type of hybrid graphene/metal interconnect structure that could be used as H1 or H2 shown in FIG. 1, in accordance with some embodiments. Multi-layer interconnect structure 300 includes a multi-layer lower metal line Mₓ, a multi-layer upper metal line Mₓ₊₁, and a via Vₓ coupling the multi-layer upper and lower metal lines. Multi-layer interconnect structure 300 features embedded graphene 112 in the form of extended layers of graphene film 112a alternating with regions of copper metal to form a composite structure. In some embodiments, multi-layer interconnect structure 300 further includes liners 107 on interior surfaces of multi-layer interconnect structure 300. Liners 107 can also have multiple layers with a total thickness T_{L}. In some embodiments, capping liners 107c are included on the top surfaces of one or more metal lines. In some embodiments, one or more liners 107 can extend across the bottom of via Vₓ as shown in FIG. 3. In some embodiments, multi-layer interconnect structure 300 further includes etch stop layers 108 on respective top surfaces of the metal lines.

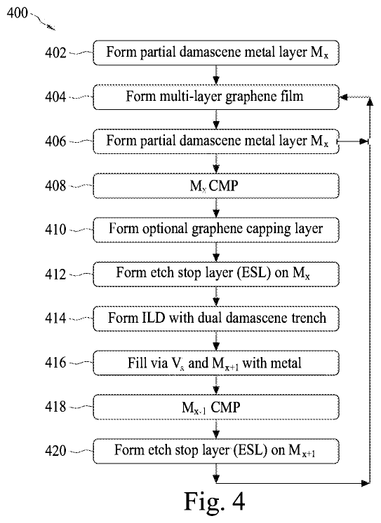

FIG. 4 illustrates a method 400 for fabricating multi-layer interconnect structure 300, according to some embodiments. For illustrative purposes, operations illustrated in FIG. 4 will be described with reference to exemplary processes for fabricating multi-layer interconnect structure 300 as illustrated in FIGS. 5A-5E, a sequence of cross-sectional views of multi-layer interconnect structure 300 at various stages of its fabrication, according to some embodiments. Operations of method 400 can be performed in a different order, or not performed, depending on specific applications. It is noted that method 400 may not produce a complete multi-layer interconnect structure 300. Accordingly, it is understood that additional processes can be provided before, during, or after method 400, and that some of these additional processes may be briefly described herein.

Referring to FIG. 4, in operations 402-412, lower metal line Mₓ can be formed as shown in FIG. 5A, in accordance with some embodiments. First, in operation 402, a damascene trench for Mₓ can be etched into ILD 106a to a depth that, when filled with metal, achieves a desired metal thickness, e.g., 600 Å-1000 Å. The trench etch process may use, for example, a fluorine-based plasma. Then, liner 107 can be deposited on the bottom and sidewalls of the damascene trench.

Referring to FIG. 4, in operation 402, after etching the damascene trench, the damascene trench can be partially filled with metal, according to some embodiments. In some embodiments, the partial metal layer, e.g., copper, can be formed using a plating process, such as electroplating or electro-less plating, or a PVD process. In some embodiments, a copper seed layer can be conformally deposited on liner 107 using a PVD process, prior to plating bulk copper.

Referring to FIG. 4, in operation 404, a multi-layer graphene film 112a can be embedded in the bulk metal using, e.g., a CVD process to deposit the multi-layer graphene film 112a on the partially-formed metal line Mₓ. The embedded multi-layer graphene film 112a can have as many as about 20 graphene atomic mono-layers, where the multi-layer graphene film 112a has a thickness in a range from about ⅔ wₘᵢₙ to about wₘₐₓ/30, where wₘᵢₙ is a minimum value and wₘₐₓ is a maximum value of metal width w for metal line Mₓ.

Referring to FIG. 4, in operation 406, the damascene trench can be filled further with metal, as in operation 402. Operations 404 and 406 can be repeated in an alternating fashion, up to about five times (for example), to create multiple layers of embedded graphene in the bulk metal. In some embodiments, lower metal line Mₓ includes between one and five embedded multi-layer graphene films 112a, alternating with regions of copper deposited in operation 404.

Referring to FIG. 4, in operation 408, lower metal line Mₓ can be polished, in accordance with some embodiments. Polishing can be accomplished using a CMP planarization process, as described above with respect to contact layer 105.

Referring to FIG. 4, in operation 410, an optional capping liner 107c is formed as shown in FIG. 5A, in accordance with some embodiments. When the trench is full, an optional capping liner 107c can be deposited over the top region of copper in operation 408. In some embodiments, capping liner 107c can be as thick as T_{Mx+1}/10.

Referring to FIG. 4, in operation 412, etch stop layer 108 is deposited as shown in FIG. 5A, in accordance with some embodiments.

Referring to FIG. 4, in operation 414, ILD 106b is formed, with a dual damascene trench 500, in accordance with some embodiments. ILD 106a and 106b are not shown in FIGS. 5A-5E for simplicity. Dual damascene trench 500 is formed and partially filled as shown in FIG. 5B, in accordance with some embodiments. Dual damascene trench 500 includes a vertical portion (e.g., extending in the z-direction) that will contain via Vₓ and a horizontal portion (e.g., extending in the x-y plane) that will contain upper metal line Mₓ₊₁. The vertical portion of dual damascene trench 500 extends downward (in the −z-direction) through etch stop layer 108 and capping liner 107c into the bulk metal of lower metal line Mₓ. Liner 107 is then formed on internal surfaces of dual damascene trench 500, including a lower trench surface 502 of dual damascene trench 500, using, for example, a conformal deposition process. Next, Vₓ and a lower region of upper metal layer Mₓ₊₁ can be filled simultaneously with copper using, for example, a plating process.

Referring to FIG. 4, in operation 416, upper metal line Mₓ₊₁ can be formed as shown in FIG. 5C, in accordance with some embodiments. Upper metal line Mₓ₊₁ can be formed by alternately depositing multi-layer films of embedded graphene 112 and regions of copper, as described above with respect to lower metal line Mₓ. Depositing upper metal line Mₓ₊₁ may over-fill dual damascene trench 500 with copper, creating excess copper 504.

Referring to FIG. 4, in operation 418, upper metal line Mₓ₊₁ can be polished as shown in FIG. 5D, in accordance with some embodiments. Polishing can be accomplished using a CMP planarization process, as described above with respect to contact layer 105. Following planarization, excess copper 504 has been removed, and a top surface of upper metal line Mₓ₊₁ is substantially co-planar with top surfaces of liner 107.

Referring to FIG. 4, in operation 420, etch stop layer 108 is formed on upper metal line Mₓ₊₁ as shown in FIG. 5E, in accordance with some embodiments. Formation of etch stop layer 108 completes multi-layer interconnect structure 300. Operations 404-420 can then be repeated to form additional dual damascene interconnect structures on top of multi-layer interconnect structure 300.

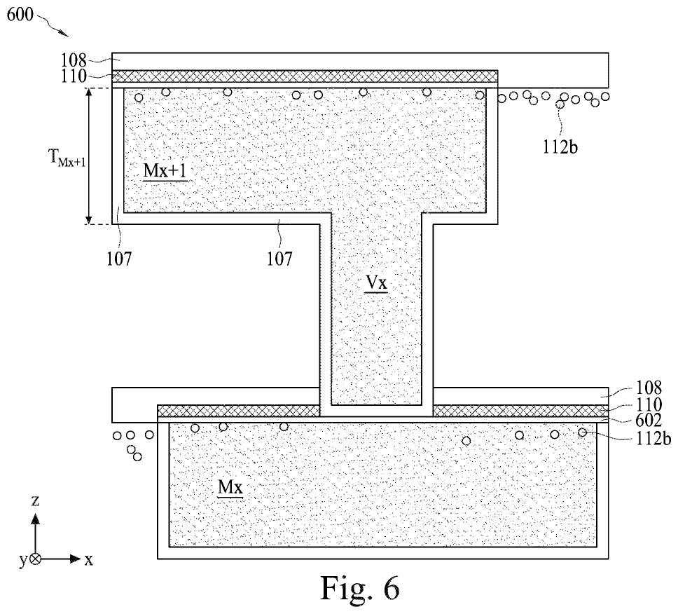

FIG. 6 shows a cross-sectional view of an implanted interconnect structure 600, e.g., an implanted hybrid graphene/metal interconnect structure that could be used as H1 or H2 as shown in FIG. 1, in accordance with some embodiments. Implanted interconnect structure 600 includes a carbon-implanted lower metal line Mₓ, a carbon-implanted upper metal line Mₓ₊₁, and a via Vₓ coupling the carbon-implanted upper and lower metal lines Mₓ₊₁ and Mₓ. The carbon implants can form a graphene capping layer 110 near the surface of metal lines Mₓ and Mₓ₊₁. In some embodiments, implanted interconnect structure 600 further includes liners 107 on interior surfaces of implanted interconnect structure 600. In some embodiments, one or more liners 107 can extend across the bottom of via Vₓ as shown in FIG. 6. In some embodiments, implanted interconnect structure 600 further includes etch stop layers 108 on top of graphene capping layer 110.

Implanted interconnect structure 600 features embedded graphene in the form of implanted carbon atoms 112b. In some embodiments, carbon atoms 112b can be charged atoms or ions. In some embodiments, carbon atoms 112b can be agglomerated into graphene islands 602, forming a partial graphene film. Such graphene islands 602 can cover, for example, between about 5% and about 100% of the top surface area of metal lines Mₓ or Mₓ₊₁. In some embodiments, carbon atoms 112b that are intended to be implanted into metal lines can be found on or near top surfaces of ILD 106a and 106b. In some embodiments, the interface between liners 107 and the tops of metal lines Mₓ and Mₓ₊₁ can be carbon-rich to enhance interfacial adhesive characteristics.

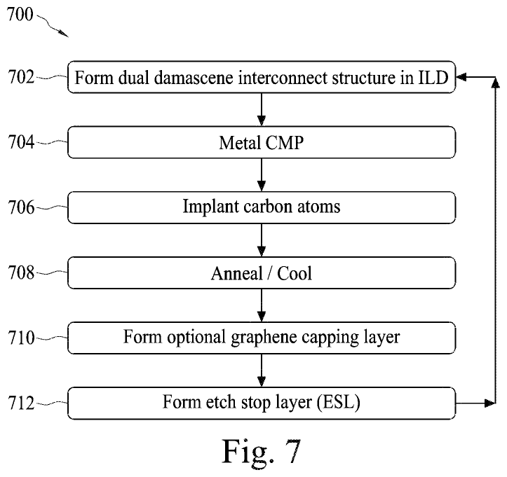

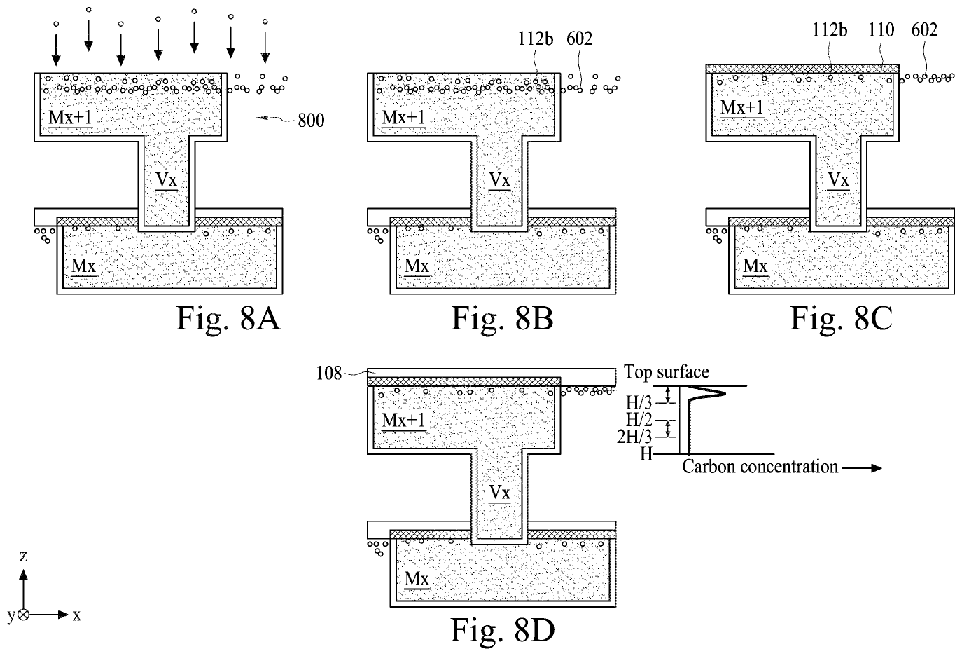

FIG. 7 illustrates a method 700 for fabricating implanted interconnect structure 600, according to some embodiments. For illustrative purposes, operations illustrated in FIG. 7 will be described with reference to exemplary processes for implanted interconnect structure 600 as illustrated in FIGS. 8A-8D, a sequence of cross-sectional views of implanted interconnect structure 600 at various stages of its fabrication, according to some embodiments. Operations of method 700 can be performed in a different order, or not performed, depending on specific applications. It is noted that method 700 may not produce a complete implanted interconnect structure 600. Accordingly, it is understood that additional processes can be provided before, during, or after method 700, and that some of these additional processes may be briefly described herein.

Referring to FIG. 7, in operation 702 a dual damascene interconnect structure 800 is formed as illustrated in FIG. 8A, in accordance with some embodiments. Interconnect structure 800 includes metal lines Mₓ and Mₓ₊₁ connected by via Vₓ. First, in operation 702, Mₓ is formed, ILD 106b is deposited, and then an L-shaped dual damascene structure is formed in ILD 106b, as described above in operations 216 and 414-416. During the trench fill process, liner 107 can be deposited on the bottom and sidewalls of the damascene trench prior to filling with bulk metal, e.g., copper, as described above in operations 216 and 416.

Referring to FIG. 7, in operation 704, a CMP planarization process is performed to planarize the top surface of upper metal line Mₓ₊₁ as illustrated in FIG. 8A, in accordance with some embodiments. Following planarization, a top surface of upper metal layer Mₓ₊₁ is substantially co-planar with top surfaces of liner 107, as shown in FIG. 8A.

Referring to FIG. 7, in operation 706, upper metal line Mₓ₊₁ is implanted with carbon as illustrated in FIG. 8A, in accordance with some embodiments. In some embodiments, a similar concentration of carbon atoms or ions—graphene islands 602—can also be present on or near the surface of ILD 106b, adjacent to upper metal line Mₓ₊₁. The presence of implanted carbon in ILD 106b may be detectable by analytical techniques, such as TEM/EDS, SEM/EDS, Auger electron spectroscopy (AES), x-ray photoelectron spectroscopy (XPS), and secondary ion mass spectroscopy (SIMS).

Referring to FIG. 7, in operation 708, annealing and cooling operations are performed as illustrated in FIG. 8B, in accordance with some embodiments. In some embodiments, upper metal line Mₓ₊₁ is annealed at a temperature in a range from about 300° C. to about 500° C., for a time interval in a range from about 15 minutes to about 60 minutes. Annealing can assist in driving implanted carbon atoms or ions 112b deeper into the bulk metal of upper metal line Mₓ₊₁ to achieve a desired carbon concentration profile. The carbon concentration profile can be adjusted so as to maximize a penetration depth H below the substantially planar surface of upper metal line Mₓ₊₁, and a peak concentration at a depth of about H/6. In some embodiments, maximum penetration depth H aligns with a bottom surface of the metal line being implanted. In some embodiments, peak concentration is between about 1.2 to about 5 times the background concentration at depths of about H/2 to 2H/3. For example, the peak concentration can be in a range from about 5 atomic % to about 10 atomic %, while the background concentration can be in a range from about 1 atomic % to about 21 atomic %. In some embodiments, the maximum penetration depth of carbon ions is in a range from about 150 Å to about 400 Å. In some embodiments, the presence of carbon atoms or ions 112b in upper metal line Mₓ₊₁ can be detected using analytical techniques, such as tunneling electron microscopy/energy dispersive spectroscopy (TEM/EDS) and scanning electron microscopy/energy dispersive spectroscopy (SEM/EDS). Such techniques may identify areas of high carbon concentration, e.g., about three times the background concentration, as graphene-implanted regions. In some embodiments, following the annealing process, cooling can occur at a rate within a range from about 5° C./sec to about 15° C./sec.

Referring to FIG. 7, in operation 710, a graphene capping layer 110 can be formed from implanted carbon atoms or ions, as illustrated in FIG. 8C, in accordance with some embodiments. Graphene capping layer 110 can be partially or fully formed. In some embodiments, implanted carbon atoms or ions 112b agglomerate into graphene islands that, collectively, can form a partial graphene capping layer 110. In some embodiments, enough carbon atoms or ions are implanted at a similar depth so they can agglomerate into graphene islands to form a continuous graphene capping layer 110. In some embodiments, each graphene element, e.g., graphene island or graphene film, can include up to 20 atomic monolayers of graphene. The thickness of graphene capping layer 110 can thus be tuned by adjusting time and implant energy parameters of the carbon implant process.

Referring to FIG. 7, in operation 712, an etch stop layer 108 is formed on top of graphene capping layer 110 as illustrated in FIG. 8D, in accordance with some embodiments. Formation of etch stop layer 108 completes implanted interconnect structure 600. Operations 702-712 can be repeated to form additional dual damascene interconnect structures on top of implanted interconnect structure 600. In some embodiments, additional interconnect structures similar to implanted interconnect structure 600, or multi-layer interconnect structure 300, or an interconnect structure without graphene, can be stacked on top of etch stop layer 108.

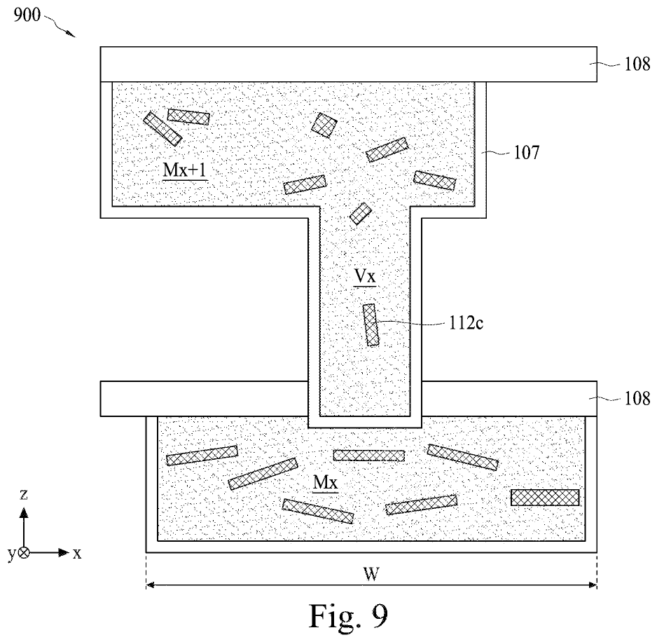

FIG. 9 shows a cross-sectional view of a distributed graphene interconnect structure 900, e.g., a distributed type of hybrid graphene/metal interconnect structure that could be used as H1 or H2 shown in FIG. 1, in accordance with some embodiments. Distributed graphene interconnect structure 900 includes a distributed graphene lower metal line Mₓ, a distributed graphene upper metal line Mₓ₊₁, and a via Vₓ coupling the distributed graphene upper and lower metal lines. Distributed graphene interconnect structure 900 features embedded graphene 112 in the form of graphene flakes or carbon nanotubes (CNTs) that are dispersed in an electroplating or electroless plating bath used to form damascene metal lines. Graphene flakes can be obtained as a commercial product, or they can be produced by depositing graphene onto a surface and then removing it. Carbon nanotubes can also be obtained in the form of a commercial powder. In some embodiments, the concentration of graphene flakes for use as an additive to liquid copper can be in a range from about 0.1% to about 5% by volume.

In some embodiments, distributed graphene interconnect structure 900 further includes liners 107 on interior surfaces of distributed graphene interconnect structure 900, including capping layers 107c. In some embodiments, one or more liners 107 can extend across the bottom of via Vₓ as shown in FIG. 9. In some embodiments, distributed graphene interconnect structure 900 further includes etch stop layers 108 on respective top surfaces of the upper and lower metal lines.

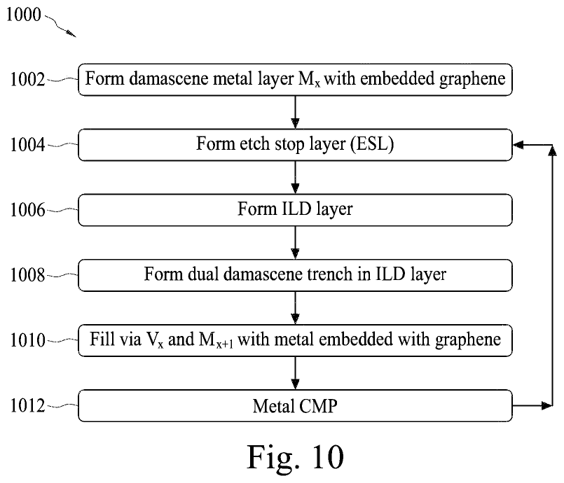

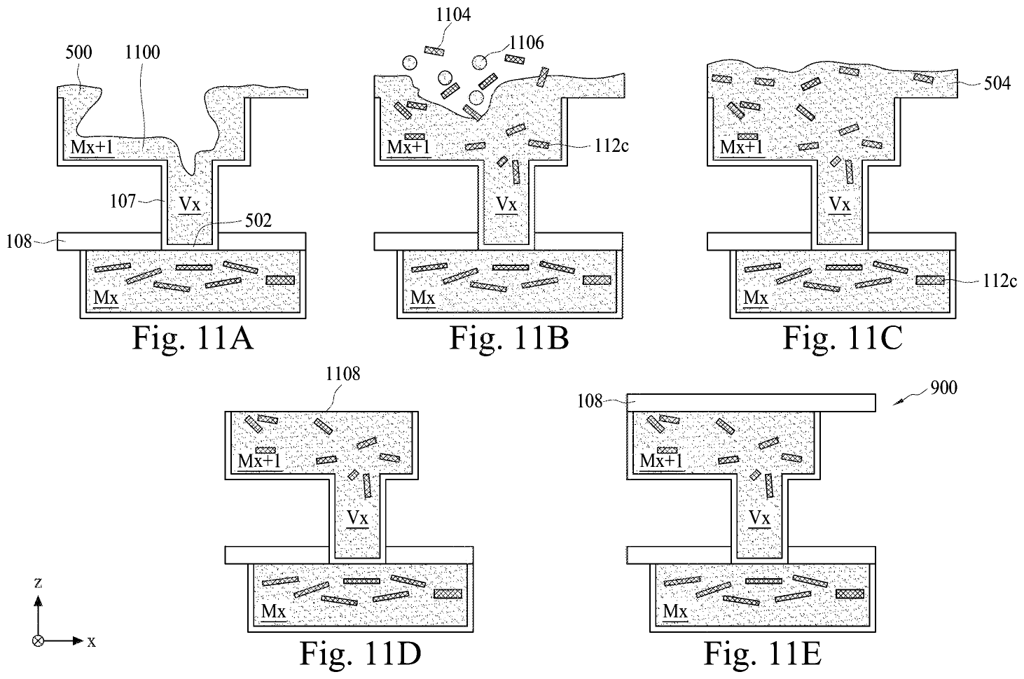

FIG. 10 illustrates a method 1000 for fabricating distributed graphene interconnect structure 900, according to some embodiments. For illustrative purposes, operations illustrated in FIG. 10 will be described with reference to exemplary processes for fabricating distributed graphene interconnect structure 900 as illustrated in FIGS. 11A-11E, a sequence of cross-sectional views of distributed graphene interconnect structure 900 at various stages of its fabrication, according to some embodiments. Operations of method 1000 can be performed in a different order, or not performed, depending on specific applications. It is noted that method 1000 may not produce a complete distributed graphene interconnect structure 900. Accordingly, it is understood that additional processes can be provided before, during, or after method 1000, and that some of these additional processes may be briefly described herein.

Referring to FIG. 10, in operation 1002, lower metal line Mₓ is formed as shown in FIG. 11A, in accordance with some embodiments. First, a damascene trench for Mₓ can be etched into ILD 106a to a depth that, when filled with metal, achieves a desired metal thickness, e.g., 600 Å-1000 Å. The trench etch process may use, for example, a fluorine-based plasma. Then, liner 107 can be deposited on the bottom and sidewalls of the damascene trench. The damascene trench can then be filled with a metal, e.g., copper, including distributed graphene elements as will be explained further below with respect to Mₓ₊₁.

Referring to FIG. 10, in operation 1004 etch stop layer 108 can be deposited as shown in FIGS. 11A-11E and described above with respect to operations 212 and 410, in accordance with some embodiments. Etch stop layer 108 is formed on upper metal line Mₓ₊₁ as shown in FIG. 11E, in accordance with some embodiments. Formation of etch stop layer 108 completes multi-layer interconnect structure 300.

Referring to FIG. 10, in operation 1006, ILD 106b is formed, in accordance with some embodiments. ILD 106a and 106b are not shown in FIGS. 5A-5E for simplicity.

Referring to FIG. 10, in operation 1008, a dual damascene trench 500 is formed and partially filled as shown in FIG. 11A, in accordance with some embodiments. Dual damascene trench 500 includes a vertical portion (e.g., extending in the z-direction) that will contain via Vₓ and a horizontal portion (e.g., extending in the x-y plane) that will contain upper metal line Mₓ₊₁. The vertical portion of dual damascene trench 500 extends downward in the −z-direction through etch stop layer 108 into the bulk metal of lower metal line Mₓ. Liner 107 is then formed on internal surfaces of dual damascene trench 500, including a lower trench surface 502 of dual damascene trench 500, using, for example, a conformal deposition process. Next, Vₓ and upper metal layer Mₓ₊₁ can be filled simultaneously with copper containing elements of graphene. In some embodiments, the copper fill process can include a copper seed layer 1100 conformally deposited on liner 107 by PVD, prior to performing a plating process to deposit bulk copper.

Referring to FIG. 10, in operation 1010, upper metal line Mₓ₊₁ is formed as shown in FIGS. 11B-11C, in accordance with some embodiments. Upper metal line Mₓ₊₁ can be formed by embedding graphene into the bulk copper, during the plating process. In some embodiments, elements of embedded graphene 112 can be incorporated in the form of, e.g., graphene flakes 1104 or carbon nanotubes 1106 dispersed throughout the plating bath. Each graphene elements of embedded graphene 112 can include up to about 20 atomic monolayers of graphene, so that the graphene element has a thickness in a range from about wₘᵢₙ/30 to about wₘᵢₙ/3 and a length in a range from about wₘᵢₙ/30 to about ⅔wₘₐₓ where wₘᵢₙ is a minimum value of metal width w and wₘₐₓ is a maximum value of metal width w for metal line Mₓ. Depositing upper metal line Mₓ₊₁ may over-fill dual damascene trench 500 with copper, creating excess copper 504.

Referring to FIG. 10, in operation 1012, upper metal line Mₓ₊₁ can be polished as shown in FIG. 11D, in accordance with some embodiments. Polishing can be accomplished using a CMP planarization process, as described above with respect to contact layer 105. Following planarization, excess copper 504 has been removed, and a top surface 1108 of upper metal line Mₓ₊₁ is substantially co-planar with top surfaces of liner 107. Operations 1004-1012 can then be repeated to deposit an etch stop layer 108 on Mₓ₊₁ and then to form additional dual damascene interconnect structures on top of distributed graphene interconnect structure 900.

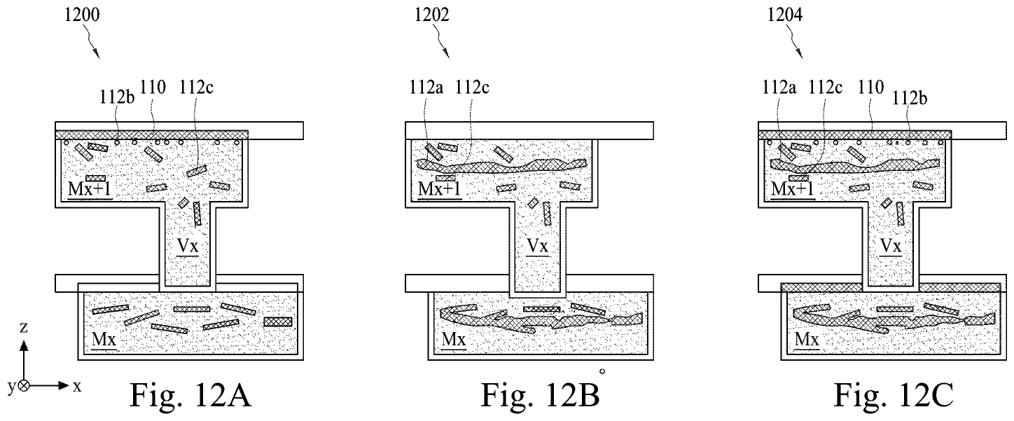

FIGS. 12A-12C illustrate various combinations of graphene interconnect structures 300, 600, and 900, that may be used as hybrid interconnect structures H1 or H2, according to some embodiments. While incorporating one form of graphene can improve performance of the metal lines, the presence of multiple forms of graphene can further improve performance.

FIG. 12A illustrates a first hybrid interconnect structure 1200 that combines features of implanted interconnect structure 600 with features of distributed graphene interconnect structure 900. First hybrid interconnect structure 1200 includes embedded elements of graphene 112 in the form of graphene flakes or carbon nanotubes 112c distributed in the copper fill, as well as graphene capping layers 110 formed by the agglomeration of implanted graphene atoms or ions 112b.

FIG. 12B illustrates a second hybrid interconnect structure 1202 that combines features of multi-layer interconnect structure 300 with features of distributed graphene interconnect structure 900. Second hybrid interconnect structure 1202 includes elements of graphene 112 in the form of multi-layer graphene films 112a combined with graphene flakes and/or carbon nanotubes 112c distributed in the copper fill of both metal lines Mₓ and Mₓ₊₁.

FIG. 12C illustrates a third hybrid interconnect structure 1204 that combines features of multi-layer interconnect structure 300 with features of implanted interconnect structure 600 and also with features of distributed graphene interconnect structure 900. Third hybrid interconnect structure 1204 includes elements of graphene 112 in the form of graphene flakes or carbon nanotubes 112c distributed in the copper fill, as well as graphene layers 112a inserted into the copper fill of both metal lines Mₓ and Mₓ₊₁, and also graphene capping layers 110 formed by agglomeration of implanted graphene atoms or ions 112b on top surfaces of the metal lines.

In some embodiments, a method includes: forming a transistor structure on a semiconductor substrate; forming a contact layer providing electrical contacts to source, drain, and gate terminals of the transistor structure; depositing a dielectric layer over the contact layer; forming, on the dielectric layer, a metal layer comprising embedded graphene; depositing an inter-layer dielectric (ILD) layer over the metal layer; etching via openings in the ILD layer; and filling the via openings with a metal.

In some embodiments, a method includes: forming a transistor on a semiconductor substrate; forming a first damascene interconnect structure over the transistor; embedding graphene in the first damascene interconnect structure; depositing an inter-layer dielectric (ILD layer; forming vias in the ILD layer; and forming a second damascene interconnect structure coupled to the first damascene interconnect structure by the vias.

In some embodiments, a structure includes: a transistor structure; an interconnect structure electrically coupled to the transistor structure, the interconnect structure including graphene elements distributed therein; an inter-layer dielectric (ILD layer on the interconnect structure; and a via in the ILD layer and in contact with the interconnect structure.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

1. A method, comprising:
forming a transistor structure on a semiconductor substrate;
forming a contact layer providing electrical contacts to source, drain, and gate terminals of the transistor structure;
depositing a dielectric layer over the contact layer;
forming, on the dielectric layer, a metal layer comprising embedded graphene;
depositing an inter-layer dielectric (ILD) layer over the metal layer;
etching openings in the ILD layer; and
filling the openings with a metal.

2. The method of claim 1, further comprising depositing a graphene capping layer in contact with the metal layer.

3. The method of claim 1, wherein forming the metal layer comprises depositing one or more multi-layer graphene films on a partially-formed metal layer.

4. The method of claim 3, wherein depositing the one or more multi-layer graphene films comprises performing a metal plating process and a graphene deposition process.

5. The method of claim 4, wherein performing the graphene deposition process comprises depositing a plurality of carbon atomic layers in one or more of a chemical vapor deposition (CVD) reactor, a plasma vapor deposition (PVD) reactor, a plasma-enhanced chemical vapor deposition (PECVD) reactor, and an atomic layer deposition (ALD) reactor.

6. The method of claim 1, wherein the forming the metal layer comprises adding graphene flakes to a metal plating solution.

7. The method of claim 1, wherein the forming the metal layer comprises adding carbon nanotubes to a metal plating solution.

8. The method of claim 1, wherein filling the via openings comprises filling the via openings with metal having an embedded graphene component.

9. The method of claim 8, wherein filling the via openings with metal having the embedded graphene component comprises filling the via openings with copper embedded with graphene flakes.

10. A method, comprising:
forming a transistor on a semiconductor substrate;
forming a first interconnect structure over the transistor;
embedding graphene in the first interconnect structure;
depositing an inter-layer dielectric (ILD) layer;
forming vertical connections in the ILD layer; and
forming a second interconnect structure coupled to the first interconnect structure by the vertical connections.

11. The method of claim 10, wherein embedding the graphene comprises implanting carbon atoms in a surface layer of the first interconnect structure.

12. The method of claim 11, further comprising annealing the implanted first interconnect structure.

13. The method of claim 12, further comprising cooling the first implanted interconnect structure to form a graphene capping layer on a top surface of the first implanted interconnect structure.

14. The method of claim 12, further comprising forming an etch stop layer on the first implanted interconnect structure.

15. A structure, comprising:
a transistor structure;
an interconnect structure electrically coupled to the transistor structure, the interconnect structure comprising graphene elements distributed therein;
an inter-layer dielectric (ILD) layer on the interconnect structure; and
a via in the ILD layer and in contact with the interconnect structure.

16. The structure of claim 15, further comprising an etch stop layer above the interconnect structure.

17. The structure of claim 15, further comprising a graphene capping layer on a top surface of the interconnect structure.

18. The structure of claim 15, wherein the graphene elements comprise one or more of graphene flakes, carbon nanotubes, and multi-layered graphene films.

19. The structure of claim 15, wherein the interconnect structure and the via comprise a metal liner.

20. The structure of claim 15, wherein the via comprises the graphene elements.
